(19) United States
(12) Patent Application Publication
(10) Pub. No.: US 2006/0164907 A1
(43) Pub. Date: Jul. 27, 2006

(54) Multiple flash memory device management

(75) Inventor: Van D. Nguyen, San Jose, CA (US)

Correspondence Address: LEFFERT JAY & POLGLAZE, P.A., P.O. BOX 581009, MINNEAPOLIS, MN, 55458-1009, US

(73) Assignee: Micron Technology, Inc.

(21) Appl. No.: 10/624,421

(22) Filed: Jul. 22, 2003

(51) Int. Cl. G11C 8/00

(52) U.S. Cl. 365/230.01

(57) ABSTRACT

Multiple memory devices can be managed as though they were one memory device. A memory device that has a logical memory address map can be replaced with multiple memory devices that each has an address range that is a subset of the logical memory address map. When one of the multiple memory devices is addressed in the logical memory address map, a corresponding physical address is generated from the logical address. The physical address is used to generate a chip select signal for that particular memory device.

### BACKGROUND OF THE INVENTION

I. Field of the Invention

The present invention relates generally to memory devices and particularly to flash memory devices.

II. Description of the Related Art

Flash memory devices have developed into a popular source of non-volatile memory for a wide range of electronic applications. Flash memory devices typically use a one-transistor memory cell that allows for high memory densities, high reliability, and low power consumption. Common uses for flash memory include portable computers, personal digital assistants (PDAs), digital cameras, and cellular telephones. Program code, system data such as a basic input/output system (BIOS), and other firmware can typically be stored in flash memory devices. Most electronic devices are designed with a single flash memory device.

Flash memory devices are manufactured in various memory densities. For example, flash memory may be manufactured in 16 megabyte (MB), 32 MB, and 64 MB as well as other densities. The availability of each type of flash memory density, however, may vary depending on market conditions. One type of memory may be easy to obtain while another may be in demand and difficult to buy.

A problem exists when an electronic device is designed to accept a flash memory device, having a particular memory density, that subsequently becomes difficult to obtain or even unavailable. The operating system of the device has been designed to access only a single range of addresses in order to access that particular flash memory device. There is a resulting need in the art for a way to replace a single flash memory device with multiple memory devices while enabling the operating system or other programs to access the new devices in a seamless fashion.

### SUMMARY

The present invention encompasses a method for managing multiple memory devices in a system having a logical address map. The logical address map includes a memory device logical address map.

The method comprises receiving a first logical address out of the range of logical addresses. The first logical address is used to determine a first physical address, out of a range of physical addresses, that corresponds to the first logical address. A chip select signal is transmitted to a first memory device of the multiple memory devices in response to the first physical address.

### BRIEF DESCRIPTION OF THE DRAWINGS

FIG. 1 shows a block diagram of one embodiment of a memory system of the present invention.

FIG. 2 shows one embodiment of a table of logical addresses and corresponding physical addresses.

FIG. 3 shows one embodiment of a table entry in accordance with the present invention.

FIG. 4 shows a flowchart of one embodiment of a memory management method of the present invention.

FIG. 5 shows an alternate embodiment of a memory system of the present invention.

### DETAILED DESCRIPTION

The embodiments of the present invention enable a single flash memory device to be replaced with multiple flash memory devices without changing the system's memory map. The embodiments of the present invention may be implemented in a system that is initially designed with a single flash memory that is replaced due to unavailability of the memory or for cost reasons. The single flash memory can be replaced by two or more smaller memories that can be addressed by the operating system or applications in a seamless fashion over non-contiguous physical address space.

While the subsequent discussion of the embodiments of the present invention refers to flash memory, any type of memory device that has similar characteristics may be used. For example non-volatile RAM (NOVRAM) or electrically erasable programmable read only memory (EEPROM) may be used.

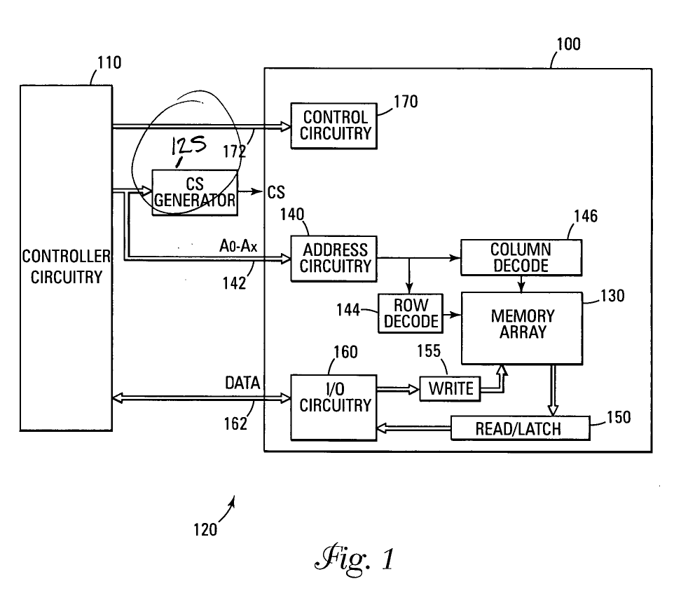

FIG. 1 is a functional block diagram of a memory device (100) of one embodiment of the present invention that is coupled to a controller circuit (110). The controller circuit (110) may be a microprocessor, a processor, or some other type of controlling circuitry. The memory device (100) and the controller (110) form part of an electronic system (120). The memory device (100) has been simplified to focus on features of the memory that are helpful in understanding the present invention.

The memory device includes an array of memory cells (130). The memory cells are non-volatile floating-gate memory cells and the memory array (130) is arranged in banks of rows and columns.

An address buffer circuit (140) is provided to latch address signals provided on address input connections A0-Ax (142). Address signals are received and decoded by a row decoder (144) and a column decoder (146) to access the memory array (130). It will be appreciated by those skilled in the art, with the benefit of the present description, that the number of address input connections depends on the density and architecture of the memory array (130). That is, the number of addresses increases with both increased memory cell counts and increased bank and block counts.

The memory device (100) reads data in the memory array (130) by sensing voltage or current changes in the memory array columns using sense/latch circuitry (150). The sense/latch circuitry, in one embodiment, is coupled to read and latch a row of data from the memory array (130). Data input and output buffer circuitry (160) is included for bi-directional data communication over a plurality of data connections (162) with the controller (110). Write circuitry (155) is provided to write data to the memory array.

Command control circuit (170) decodes signals provided on control connections (172) from the processor (110). These signals are used to control the operations on the memory array (130), including data read, data write, and erase operations.

Chip select generation circuitry (125) generates the chip select signals for the memory device (100). This circuitry (125) uses the address connections (142) from the controller (110) to generate the appropriate chip select signal depending on the address present on the address connections (142).

The flash memory device illustrated in FIG. 1 has been simplified to facilitate a basic understanding of the features of the memory. A more detailed understanding of internal circuitry and functions of flash memories are known to those skilled in the art.

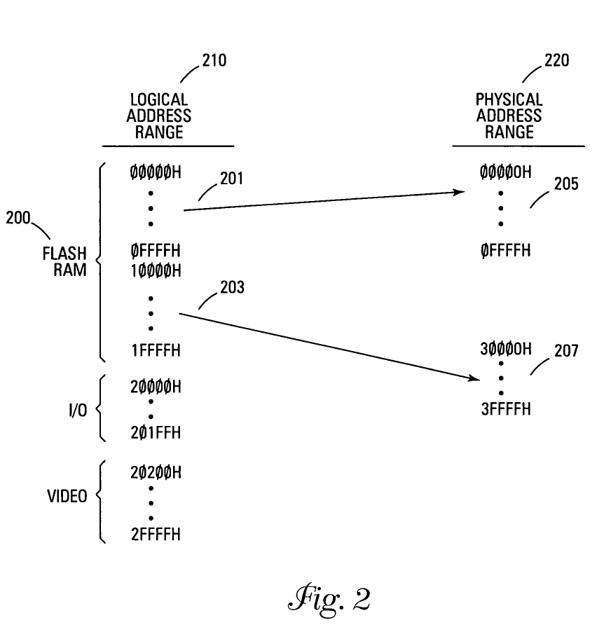

FIG. 2 illustrates one embodiment of a table of logical addresses and their corresponding physical addresses. This figure is for illustration purposes only and does not limit the present invention to any memory address range or ranges.

An electronic system, such as the embodiment of FIG. 1, is designed with a logical address map (210) of all of the memory and input/output (I/O) of the system. This map is used by the operating system and/or applications running on the system when it is desired to access a particular memory or I/O. For example, if the electronic system is a digital camera and a picture is being written to flash RAM, the system would write to a memory address in the range of 00000H to 1FFFFH to store the picture.

The logical address range (210) of FIG. 2 has a flash memory address range (200) of 128 MB. For purposes of illustration, the system might also have an address range from 20000H to 201FFH for I/O and 20200H to 2FFFFH for video memory.

If the electronic system has a single 128 MB flash RAM device, only a single chip select is required to access the device. In this case, any program or operating system that generates an address in the range of 00000H to 1FFFFH would generate a chip select for the 128 MB flash RAM.

However, if the electronic system has two 64 MB flash RAM devices, its physical address range (220) might be different than the logical address range (210). The electronic system might split up the single flash memory address range (200) into two logical address sub-ranges (201 and 203) for the two flash RAMs. Each logical address sub-range (201 and 203) could then be mapped to different physical address ranges (205 and 207 respectively).

In such an embodiment, the system would have to generate two separate chip selects, one for each physical address range (205 and 207) In the embodiment of FIG. 2, the two physical address ranges are 00000H to 0FFFFH for the first 64 MB logical address range (201) and 30000H to 3FFFFH for the second 64 MB logical address range (203). The physical address ranges (205 and 207) for the flash memory may be contiguous or non-contiguous. FIG. 2 illustrates a non-contiguous embodiment.

The embodiments of the present invention are not limited to two separate physical address ranges to replace the single logical address range. An alternate embodiment may use four 32 MB memory devices in place of the 128 MB device. This would require four physical address ranges. Still other alternate embodiments may be designed with a flash memory other than 128 MB. For example, the electronic system may have a logical address range of 64 MB.

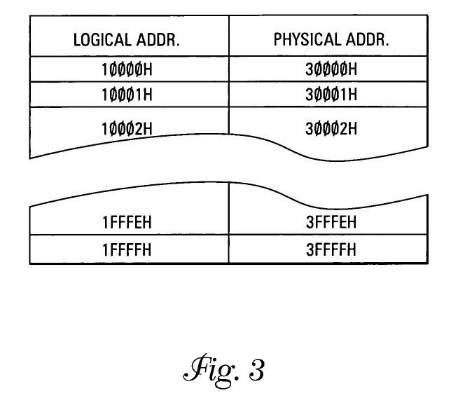

FIG. 3 illustrates one embodiment of memory map look-up table entries in accordance with the present invention. In this embodiment, the logical address 10000H maps to 30000H and 10001H maps to 30001H. This continues for the range of the logical addresses assigned to the flash memory. The operating system or other applications access a table such as is illustrated in FIG. 3 in order to determine the physical memory location of the memory to which the application wishes to write.

For example, if the operating system receives a request to write data to logical memory address 10002H, it checks the table to determine that logical memory address maps to physical memory address 30002H. The controller circuit then outputs that physical address on the address lines in order to generate the appropriate chip select for the appropriate memory device.

A memory map look-up table is only one embodiment for generating a corresponding physical address for a logical address. In an alternate embodiment, the controller circuit or a management device generates the physical address by adding a predetermined address offset to the logical address.

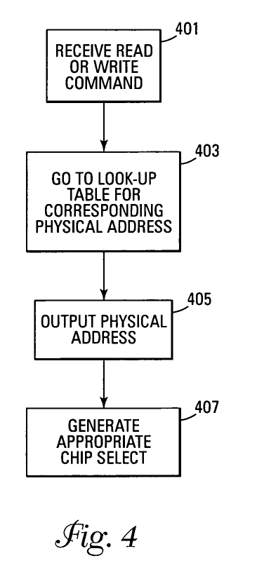

FIG. 4 illustrates a flowchart of one embodiment of a flash memory management method of the present invention. The controller circuit receives a read or write command from an operating system or other software application (401). The read or write command contains a logical address from or to which the application desires to read or write data. The controller accesses a look-up table in memory to find the corresponding physical address (403) for that particular logical address. The look-up table may be stored in RAM, ROM, flash RAM, or any other memory accessible by the controller.

The controller can then output the physical address (405) to the chip select generation circuitry over the address lines. The chip select generation circuitry uses the addresses from the controller in order to generate (407) the various chip select signals. For example, if the address that is output is in the first 64 MB physical address range of FIG. 2, a first chip select signal is generated. If the address is in the second 64 MB physical address range, a second chip select signal is generated.

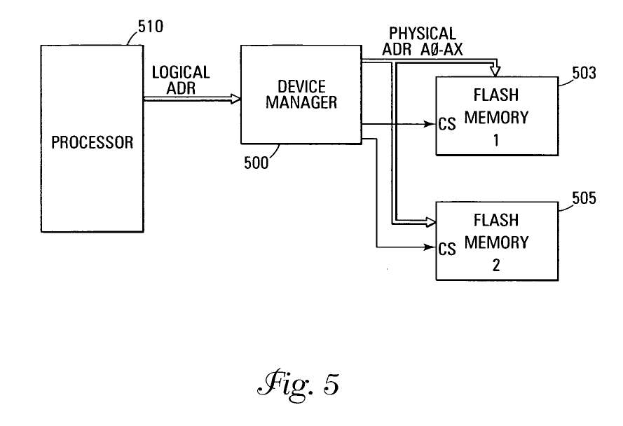

The above-described embodiment describes a controller and chip select circuitry to generate the addresses and chip select signals. An alternate embodiment of this system is illustrated in FIG. 5. The system of FIG. 5 uses a device manager (500) that, in one embodiment, contains the look-up table functions of the controller circuitry and the chip select signal generation function of the embodiment of FIG. 1.

In one embodiment, the device manager is a software module that is stored in memory, such as one of the multiple flash memory devices (503 and 505). In another embodiment, the device manager is a hardware device such as an application specific integrated circuit (ASIC) or a field programmable gate array (FPGA).

The device manager (500) receives the logical addresses from the processor (510) that is executing an operating system or other software application. The device manager (500) then accesses a look-up table, stored in the device manager (500) or some memory device, in order to generate the appropriate physical address and chip select signals for the multiple flash memories (503 and 505).

In summary, the embodiments of the present invention enable multiple memory devices at non-contiguous physical addresses to be addressed as if they were a single device. With the embodiments of the present invention, multiple smaller memory devices that are more readily available or less expensive can be substituted for one larger memory device. This is accomplished without changing the logical memory map of the electronic system.

Numerous modifications and variations of the present invention are possible in light of the above teachings. It is therefore to be understood that within the scope of the appended claims, the invention may be practiced otherwise than as specifically described herein.

1. A method for managing multiple memory devices over a range of logical addresses, the method comprising:
receiving a command comprising a first logical address from the range of logical addresses;
determining a first physical address, from a range of physical addresses, that corresponds to the first logical address; and
generating a chip select signal in response to the first physical address.

2. The method of claim 1 wherein the range of physical addresses is contiguous.

3. The method of claim 1 wherein the range of physical addresses is substantially equivalent to the range of logical addresses.

4. The method of claim 1 wherein the multiple memory devices are flash RAM devices.

5. The method of claim 1 wherein the range of logical addresses are contiguous and the corresponding range of physical addresses is non-contiguous and comprised of a plurality of physical address sub-ranges.

6. The method of claim 5 wherein a chip select signal is generated for each physical address sub-range.

7. A method for managing multiple flash memory devices over a range of logical addresses, the method comprising:
receiving a command comprising a first logical address from the range of logical addresses;
determining a first physical address, from a range of non-contiguous physical addresses, that corresponds to the first logical address; and
generating a chip select signal in response to the first physical address.

8. The method of claim 7 wherein receiving the command comprises a controller circuit executing an application in which the first logical address is read from memory along with the command.

9. The method of claim 7 wherein receiving the command comprises a device manager receiving the first logical address from a controller circuit.

10. The method of claim 9 wherein the device manager generates the chip select signal in response to the first physical address.

11. A method for managing multiple flash memory devices over a range of logical addresses, the method comprising:
a controller circuit executing an application;
the controller circuit receiving a first logical address from the range of logical addresses in response to the execution of the application;
determining a first physical address, from a range physical addresses comprising a plurality of non-contiguous sub-ranges, that corresponds to the first logical address;
outputting the first physical address to chip select generation circuitry; and
the chip select generation circuitry generating a chip select signal in response to the first physical address.

12. The method of claim 11 wherein each of the plurality of non-contiguous sub-ranges is substantially equal to a logical address range of a flash memory device of the multiple flash memory devices.

13. An electronic system having a logical address map comprising a flash memory logical address range for a designed memory device, the system comprising:
a plurality of flash memory devices having a combined physical address range substantially equivalent to the flash memory logical address range;
a controller circuit coupled to the plurality of memory devices, the controller circuit capable of generating a first physical address from the combined physical address range in response to a first logical address received from an executing software application; and
a chip select generation circuit coupled to the controller circuit and the plurality of memory devices, the chip select generation circuit transmitting a chip select signal to one of the plurality of memory devices in response to the first physical address.

14. The system of claim 13 wherein the controller circuit is coupled to the plurality of flash memory devices through a plurality of address lines.

15. The method of claim 13 wherein the controller circuit generates the first physical address in response to a look-up table entry comprising the first logical address and the first physical address.

16. The method of claim 13 wherein the controller circuit generates the first physical address in response to adding an address offset to the first logical address.

17. An electronic system having a logical address map comprising a flash memory logical address range for a designed memory device, the system comprising:
a processor that executes a software application, thereby generating a first logical address;
a plurality of flash memory devices having a combined physical address range substantially equivalent to the flash memory logical address range, the plurality of flash memory devices coupled to the processor over address lines; and
a device manager coupled to the plurality of flash memory devices and the processor, the device manager comprising:
a controller function capable of generating a first physical address from the combined physical address range in response to the first logical address; and
a chip select generation function capable of transmitting a chip select signal to one of the plurality of memory devices in response to the first physical address.

18. The electronic system of claim 17 wherein the controller function uses a look-up table stored in memory to generate the physical address in response to the logical address.

19. The electronic system of claim 17 wherein the controller function adds an address offset to the logical address to generate the physical address.

20. In an electronic system that is controlled by a processor, a method for managing multiple flash memory devices over a range of logical addresses, the method comprising:
the processor executing a software application;
the processor receiving a first logical address from the range of logical addresses in response to the execution of the application;
the processor determining a first physical address, from a range physical addresses comprising a plurality of non-contiguous address sub-ranges, that corresponds to the first logical address;
the processor outputting the first physical address to chip select generation circuitry; and
the chip select generation circuitry transmitting a chip select signal, generated in response to the first physical address, to a first flash memory device of the multiple flash memory devices.
